(19) United States
(12) Patent Application Publication
(10) Pub. No.: US 2026/0332151 A1
(43) Pub. Date: Oct. 22, 2026

(54) DIGITAL PHASE LOCK LOOP AND METHOD OF OPERATING THE SAME

(71) Applicant: Samsung Electronics Co., Ltd., Suwon-si (KR)

(72) Inventors: Jaehyouk CHOI, Seoul (KR); Seheon JANG, Seoul (KR); Munjae CHAE, Seoul (KR)

(73) Assignees: Samsung Electronics Co., Ltd., Suwon-si (KR); Seoul National University R&DB Foundation, Seoul (KR)

(21) Appl. No.: 19/569,666

(22) Filed: Mar. 17, 2026

(30) Foreign Application Priority Data
Apr. 18, 2025 (KR) 10-2025-0051121

(51) Int. Cl. H03L 7/081; H03L 7/089; H03M 3/00

(52) U.S. Cl. CPC H03L 7/0818; H03L 7/089; H03M 3/344

(57) ABSTRACT

A digital phase lock loop circuit includes a phase detector to: receive a first reference signal and a first divided signal, selectively perform a delay operation on one of a second reference signal corresponding to the first reference signal and a second divided signal corresponding to the first divided signal, based on a first quantization noise correction code and a second quantization noise correction code, and output a phase difference code based on a phase difference between the second reference signal and the second divided signal on either of which the delay operation is performed; a digital loop filter to filter the phase difference code; an oscillator to generate an output signal based on the filtered phase difference code; a delta-sigma modulator to output a quantization noise signal and a division control signal based on first division ratio data and second division ratio data for the output signal.

### CROSS-REFERENCE TO RELATED APPLICATION

This application is based on and claims priority under 35 U.S.C. § 119 to Korean Patent Application No. 10-2025-0051121, filed on Apr. 18, 2025, in the Korean Patent Office, the disclosure of which is incorporated herein in its entirety by reference.

### BACKGROUND

The present disclosure relates to a digital phase lock loop circuit and a method of operating the digital phase lock loop circuit.

Phase lock loop circuits may generate signals having target frequencies required in various electronic devices such as communication systems and processors. Among them, digital phase lock loop circuits generate signals through digital circuits, and as integration efficiency improves along with the miniaturization trend of semiconductor processes, they are competitive in terms of power saving and miniaturization compared to analog phase lock loop circuits.

In general, digital phase lock loop circuits adopt fractional phase lock loop circuits that perform division operation with a fractional division ratio to more finely control the frequency of the generated signal. A fractional phase lock loop circuit may include a delta-sigma modulator that adjusts the division ratio of a generated signal in fractional units, and perform a compensation operation for quantization noise generated by delta-sigma modulation.

However, when an amplitude of the quantization noise increases, thermal noise increases during the compensation operation, which may result in additional noise due to power efficiency degradation and thermal noise during the compensation operation.

### SUMMARY

Provided are a digital phase lock loop circuit and a method of operating the digital phase lock loop circuit that improves noise and power efficiency of operation due to thermal noise.

Provided are a digital phase lock loop circuit and a method of operating the digital phase lock loop circuit with improved area efficiency.

Provided are a digital phase lock loop circuit and a method of operating the digital phase lock loop circuit that improves convergence time required to correct nonlinearity and phase error for quantization noise.

According to an aspect of the disclosure, a digital phase lock loop circuit includes: a phase detector configured to: receive a first reference signal and a first divided signal, selectively perform a delay operation on one of a second reference signal corresponding to the first reference signal and a second divided signal corresponding to the first divided signal, based on a first quantization noise correction code and a second quantization noise correction code, and output a phase difference code based on a phase difference between the second reference signal and the second divided signal on either of which the delay operation is performed; a digital loop filter configured to filter the phase difference code; an oscillator configured to generate an output signal based on the filtered phase difference code; a delta-sigma modulator configured to output a quantization noise signal and a division control signal based on first division ratio data and second division ratio data for the output signal; an accumulation circuit configured to output a quantization noise code by performing an accumulation operation on the quantization noise signal; a divider configured to output the first divided signal by dividing a frequency of the output signal based on the division control signal; and a correction circuit configured to: generate the first quantization noise correction code and the second quantization noise correction code by performing a correction operation on the quantization noise code, and provide the first quantization noise correction code and the second quantization noise correction code to the phase detector.

According to an aspect of the disclosure, a digital phase lock loop circuit includes: a phase detector including: a first buffer circuit configured to output a second reference signal to a first node by performing a buffering operation on a first reference signal, a second buffer circuit configured to output a second divided signal to a second node by performing a buffering operation on a first divided signal, a switch capacitor array at least a portion of which is configured to be selectively connected to the first node and the second node, and a latch circuit configured to store a phase difference code for a phase difference between the second reference signal and the second divided signal; a digital loop filter configured to filter the phase difference code; an oscillator configured to generate an output signal based on the filtered phase difference code; a delta-sigma modulator configured to output a quantization noise signal and a division control signal based on first division ratio data and second division ratio data for the output signal; an accumulation circuit configured to output a quantization noise code by performing an accumulation operation on the quantization noise signal; a divider configured to output the first divided signal by dividing a frequency of the output signal based on the division control signal; and a correction circuit configured to: generate a first quantization noise correction code and a second quantization noise correction code by performing a correction operation on the quantization noise code, and provide the first quantization noise correction code and the second quantization noise correction code to the phase detector.

According to an aspect of the disclosure, a method of operating a digital phase lock loop circuit, includes: receiving a first reference signal, a first quantization noise correction code corresponding to the first reference signal, a first divided signal, and a second quantization noise correction code corresponding to the first divided signal; outputting a buffering reference signal to a first node by performing a buffering operation on the first reference signal, and outputting a buffering divided signal to a second node by performing a buffering operation on the first divided signal; selectively connecting at least a portion of a switch capacitor array to the first node or the second node, based on the first quantization noise correction code and the second quantization noise correction code; generate a phase difference code by detecting a phase difference between the buffering reference signal and the buffering divided signal; and storing the phase difference code.

According to an aspect of the disclosure, a digital phase lock loop circuit includes: a phase detector configured to: receive a first reference signal, a first quantization noise correction code corresponding to the first reference signal, a first divided signal, and a second quantization noise correction code corresponding to the first divided signal, delay a second reference signal for the first reference signal based on the first quantization noise correction code, delay a second divided signal for the first divided signal based on the second quantization noise correction code, and output a phase difference code based on a phase difference between the second reference signal and the second divided signal; a digital loop filter configured to filter the phase difference code; an oscillator configured to generate an output signal based on the filtered phase difference code; a delta-sigma modulator configured to output a quantization noise signal and a division control signal, based on first division ratio data and second division ratio data for the output signal; an accumulation circuit configured to output a quantization noise code by performing an accumulation operation on the quantization noise signal; a divider configured to output the first divided signal by dividing a frequency of the output signal based on the division control signal; and a correction circuit configured to output the first quantization noise correction code and the second quantization noise correction code, which are mutually exclusive, by performing a correction operation on the quantization noise code.

### BRIEF DESCRIPTION OF DRAWINGS

The above and other aspects, features, and advantages of certain embodiments of the disclosure will be more apparent from the following description taken in conjunction with the accompanying drawings, in which:

FIG. 1 is a block diagram illustrating a digital phase lock loop circuit according to some embodiments;

FIG. 2 is a block diagram illustrating a phase detector according to some embodiments;

FIG. 3 is a block diagram illustrating a calibration circuit according to some embodiments;

FIGS. 4 to 6 are diagrams illustrating quantization noise between a divided signal and a reference signal input to a phase detector according to some embodiments;

FIG. 7 illustrates an example of a probability density function due to quantization noise occurring in a digital phase lock loop circuit according to some embodiments;

FIG. 8 is a flowchart illustrating a method of operation of a digital phase lock loop circuit according to some embodiments;

FIGS. 9 to 12 are drawings for explaining an operation method of a digital phase lock loop circuit according to some embodiments; and

FIG. 13 is a block diagram illustrating an electronic device according to some embodiments.

### DETAILED DESCRIPTION OF EMBODIMENTS

Hereinafter, various embodiments of the present disclosure will be described in detail with reference to the attached drawings so that a person having ordinary skill in the art to which the present disclosure pertains may easily implement the present disclosure. The present disclosure may be embodied in many different forms and is not limited to the embodiments described herein.

In order to clearly explain the present disclosure, parts irrelevant to the description are omitted, and identical or similar reference numerals are given to identical or similar components throughout the specification.

Additionally, throughout the specification, whenever a portion is said to “include” a component, this does not mean that it excludes other components, but rather that it may include other components, unless otherwise specifically stated.

Additionally, a specific number set forth in a claim, even if explicitly recited in the claim, should not be construed as a limitation to the specific number in claims where such recitation does not exist. For example, subsequent dependent claims may include the phrases “at least one” and “one or more” to aid understanding. However, the use of such a construction should not be understood as being limited by the ambiguous article ‘one’, which is described for the sake of one example.

Moreover, when a convention such as ‘at least one of A, B, or C’ is used, such a phrase will be well understood by a person skilled in the art (i.e., ‘a system comprising at least one of A, B, or C’ includes, but is not limited to, A alone, B alone, C alone, A and B, A and C, B and C, and/or A, B, and C together). Or, words and/or phrases in the detailed description or claims or drawings having two or more separate alternative terms should be considered as possibly including one, or either, or both terms. For example, the phrase ‘A or B’ should be understood to include the possibilities of ‘A’, or ‘B’, or ‘A and B’.

The terms “module,” “unit,” “part,” and the like, as used in this document, are terms intended to refer to a component that performs at least one function or operation, and such a component may be implemented as hardware or software, or as a combination of hardware and software.

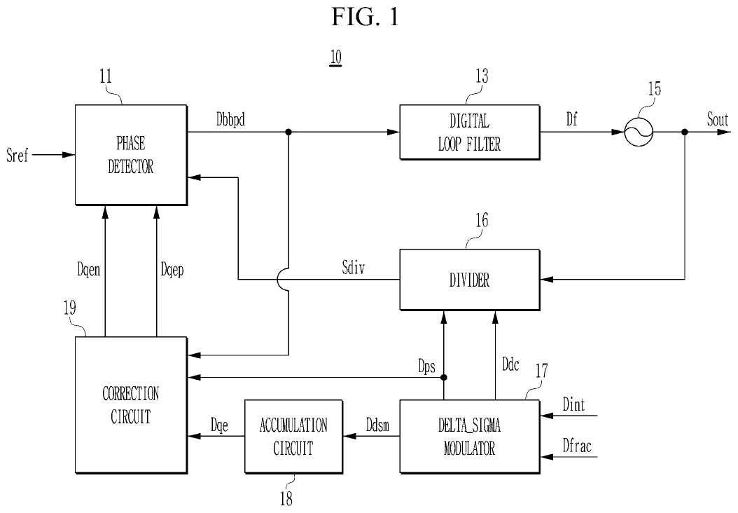

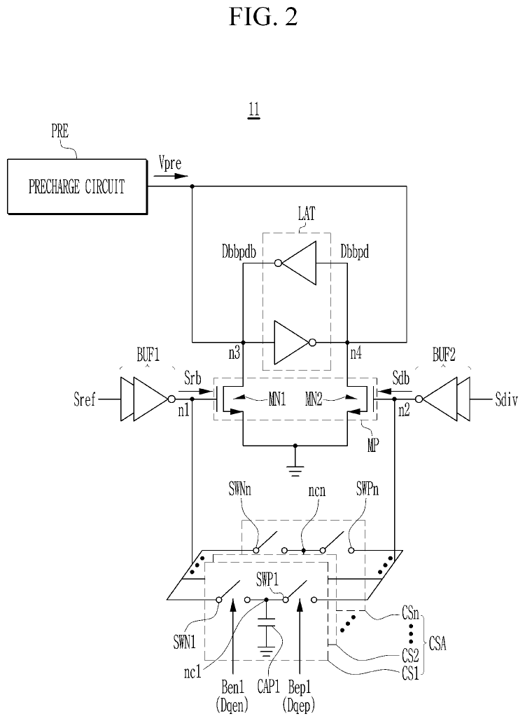

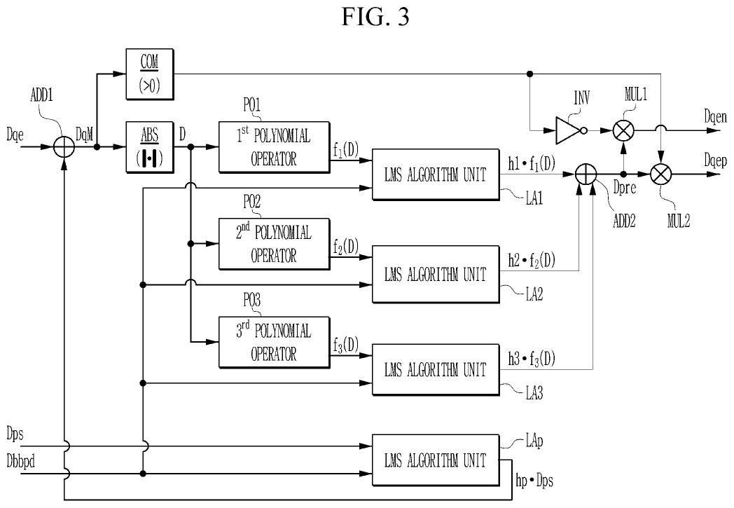

FIG. 1 is a block diagram illustrating a digital phase lock loop circuit according to some embodiments. FIG. 2 is a block diagram illustrating a phase detector according to some embodiments. FIG. 3 is a block diagram illustrating a calibration circuit according to some embodiments.

Referring to FIG. 1, a digital phase lock loop circuit 10 may include a phase detector 11, a digital loop filter 13, an oscillator 15, a divider 16, a delta-sigma modulator 17, an accumulation circuit 18, and a correction circuit 19.

The digital phase lock loop circuit 10 may be a phase lock loop or a phase lock loop circuit. The digital phase lock loop circuit 10 may output an output signal Sout from a reference signal Sref. The reference signal Sref may oscillate at a constant frequency and may be generated, for example, from a crystal oscillator. The digital phase lock loop circuit 10 may generate an output signal Sout having a target frequency required by a functional block. The function block may process a signal based on the output signal Sout, and the signal processing speed of the function block may depend on the frequency of the output signal Sout, while a jitter of the output signal Sout may limit the high-speed operation of the function block. According to this phenomenon, the digital phase lock loop circuit 10 may block the influence of a noise causing jitter, thus may generate the output signal Sout with reduced jitter.

The digital phase lock loop circuit 10 may be a ‘digital’ phase lock loop. One component of the digital phase lock loop circuit 10 may include a digital circuit configured to generate a digital code based on the reference signal Sref and the output signal Sout. One component of the digital phase lock loop circuit 10 may generate an output signal Sout having a target frequency based on the generated digital code.

The digital phase lock loop circuit 10 may be a ‘fractional’ phase lock loop circuit. The digital phase lock loop circuit 10 may divide the output signal Sout by a ‘fractional’ division ratio and generate a divided signal Sdiv for the output signal Sout, which is a feedback signal. The digital phase lock loop circuit 10 may detect a phase lead or a phase lag by comparing a phase between the reference signal Sref and the divided signal Sdiv, and may output the output signal Sout based on the phase comparison result.

According to some embodiments, the digital phase lock loop circuit 10 may be implemented as an integrated circuit manufactured by a semiconductor process in an embodiment, and may be included in at least one semiconductor package including the integrated circuit and a board on which the semiconductor package is mounted in an embodiment.

In addition to the reference signal Sref and the divided signal Sdiv, the phase detector 11 may receive a first quantization noise correction code Dqen, and a second quantization noise correction code Dqep. The reference signal Sref may be received from a crystal oscillator included in the digital phase lock loop circuit 10 or a device external to the digital phase lock loop circuit 10. The divided signal Sdiv may be received from the divider 16 and may be a feedback signal. The first quantization noise correction code Dqen and the second quantization noise correction code Dqep may be received from the correction circuit 19 and may be compensation signals for quantization noise between the reference signal Sref and the divided signal Sdiv.

The phase detector 11 may selectively delay one of the reference signal Sref and the divided signal Sdiv, based on the first quantization noise correction code Dqen and the second quantization noise correction code Dqep. The phase detector 11 may perform a compensation operation for quantization noise between the reference signal Sref and the divided signal Sdiv, through the above delay operation performed by the phase detector 11. The phase detector 11 may delay the reference signal Sref based on the first quantization noise correction code Dqen and may delay the divided signal Sdiv based on the second quantization noise correction code Dqep. According to some embodiments, the first quantization noise correction code Dqen and the second quantization noise correction code Dqep may be mutually exclusive. That is, if one of the first quantization noise correction code Dqen and the second quantization noise correction code Dqep is a valid code, the other one may be a NULL code.

The phase detector 11 may detect the phase difference between the compensated reference signal Sref and the divided signal Sdiv based on the first quantization noise correction code Dqen and the second quantization noise correction code Dqep. The phase detector 11 may generate and store a phase difference code Dbbpd based on the detection result, and provide the phase difference code Dbbpd to the digital loop filter 13 and the correction circuit 19. According to some embodiments, the phase detector 11 may be implemented as a Bang-Bang phase detector (BBPD), and the phase difference code Dbbpd may include phase difference information between the reference signal Sref and the divided signal Sdiv as bit data.

In FIG. 2, the phase detector 11 may include a first buffer circuit BUF1, a second buffer circuit BUF2, a switch capacitor array CSA, a differential transistor pair MP, a latch circuit LAT, and a precharge circuit PRE.

The first buffer circuit BUF1 may receive the reference signal Sref and perform a buffering operation on the reference signal Sref to provide a buffering reference signal Srb to the first node n1.

The second buffer circuit BUF2 may receive the divided signal Sdiv and perform a buffering operation on the divided signal Sdiv to provide a buffering divided signal Sdb to the second node n2.

The switch capacitor array CSA may include a plurality of switch capacitor elements CS1, CS2, . . . , CSn connected in parallel between the first node n1 and the second node n2. The “n” is a natural number greater than or equal to 3.

Each of the plurality of switch capacitor elements CS1, CS2, . . . , CSn may include at least three parts, (1) a capacitor having one end grounded and the other end connected to a common node, (2) a first switch connecting between the common node and a first node n1, and (3) a second switch connecting between the common node and a second node n2. Referring to the first switch capacitor element CS1 as an example, the first switch capacitor element CS1 may include (1) a first capacitor CAP1 including one end connected to a first common node nc1 and the other end grounded, (2) a first_1 switch SWN1 electrically connecting between the first common node nc1 and the first node n1, and (3) a second_1 switch SWP1 electrically connecting between the first common node nc1 and the second node n2. Each of the remaining second to n-th switch capacitor elements CS2, CS3, . . . , CSn may have a circuit structure corresponding to the circuit structure of the first switch capacitor element CS1, and the n-th switch capacitor element CSn may include (1) an n-th capacitor including one end connected to an n-th common node non and the other end grounded, (2) a first_n switch SWNn electrically connecting between the n-th common node non and the first node n1, and (3) a second_n switch SWPn electrically connecting between the n-th common node non and the second node n2.

Each of the first switch and the second switch in the plurality of switch capacitor elements CS1, CS2, . . . , CSn may be controlled by bit data of the first quantization noise correction code Dqen and bit data of the second quantization noise correction code Dqep. Referring to the first switch capacitor element CS1 as an example, the first_1 switch SWN1 may perform a short-circuit operation or an open-circuit operation based on the first_1 bit Ben1 of the first quantization noise correction code Dqen, and the second_1 switch SWP1 may perform a short-circuit operation or an open-circuit operation based on the second_1 bit Bep1 of the second quantization noise correction code Dqep.

At least a portion of the switch capacitor array CSA may be selectively connected to the first node n1 and the second node n2, based on mutually exclusive characteristics of the first quantization noise correction code Dqen and the second quantization noise correction code Dqep. In response to or based on at least a portion of the switch capacitor array CSA being electrically coupled to the first node n1 by the short-circuit operation implemented based on the first quantization noise correction code Dqen, the switch capacitor array CSA may be electrically isolated from the second node n2 by the open-circuit operation implemented based on the second quantization noise correction code Dqep. Conversely, in response to at least a portion of the switch capacitor array CSA being electrically coupled to the second node n2 by the short-circuit operation implemented based on the second quantization noise correction code Dqep, the switch capacitor array CSA may be electrically isolated from the first node n1 by the open-circuit operation implemented based on the first quantization noise correction code Dqen.

That is, each of the first switch and the second switch in the plurality of switch capacitor elements CS1, CS2, . . . , CSn may selectively connect between the first node n1 and the common node or between the second node n2 and the common node based on the mutually exclusive characteristics of the first quantization noise correction code Dqen and the second quantization noise correction code Dqep.

For example, in response to the first_1 switch SWN1 performing the short-circuit operation based on the first_1 bit Ben1 being logic high level, the second_1 switch SWP1 may perform the open-circuit operation based on the second_1 bit Bep1 being logic low level. Additionally, in response to or based on at least a portion of the first switches within the plurality of switch capacitor elements CS1, CS2, . . . , CSn performing the short-circuit operation with respect to the first node n1, the second switches within the plurality of switch capacitor elements CS1, CS2, . . . , CSn may perform the open-circuit operation. Conversely, in response to or based on the second_1 switch SWP1 performing the short-circuit operation based on the second_1 bit Bep1 being logic high level, the first_1 switch SWN1 may perform the open-circuit operation based on the first_1 bit Ben1 being logic low level. Additionally, in response to or based on at least a portion of the second switches within the plurality of switch capacitor elements CS1, CS2, . . . , CSn performing the short-circuit operation with respect to the second node n2, the first switch within the plurality of switch capacitor elements CS1, CS2, . . . , CSn may perform the open-circuit operation.

In response to or based on at least a portion of the switch capacitor array CSA being selectively connected to the first node n1 or the second node n2, the buffering reference signal Srb or the buffering divided signal Sdb may be selectively delayed.

For example, in response or based on to at least a portion of the switch capacitor array CSA being connected to the first node n1, the buffering reference signal Srb may be delayed and the switch capacitor array CSA may be disconnected from the second node n2. Additionally, in response to or based on at least a portion of the switch capacitor array CSA being connected to the second node n2, the buffering divided signal Sdb may be delayed and the switch capacitor array CSA may be disconnected from the first node n1.

At least a portion of the switch capacitor array CSA is selectively connected to the first node n1 or the second node n2 so that, during the delay for the buffering reference signal Srb or the buffering divided signal Sdb, at least a portion of the capacitors within the switch capacitor array CSA may be charged and generate heat. In the above delay operation, the voltage slope at the edge of the buffering reference signal Srb or the edge of the buffering divided signal Sdb may become les steep, and the transition point, which is the center of the edge of the buffering reference signal Srb or the buffering divided signal Sdb, may be delayed.

The phase detector 11 may perform delay operations for both the buffering reference signal Srb and the buffering divided signal Sdb through the arrangement of the switch capacitor array CSA, thereby narrowing the delay range compared to performing the delay operation for only one specific signal. The phase detector 11 may perform a compensation operation for quantization noise between the buffering reference signal Srb and the buffering divided signal Sdb using a relatively small number of switch capacitor elements through the arrangement of the switch capacitor array CSA.

A differential transistor pair MP and a latch circuit LAT may operate together to detect and amplify a voltage difference between the buffering reference signal Srb of the first node n1 and the buffering divided signal Sdb of the second node n2, and apply the amplified voltage to a third node n3 and a fourth node n4. Through the above amplification operation, the differential transistor pair MP and the latch circuit LAT may detect the phase difference between the buffering reference signal Srb and the buffering divided signal Sdb. The latch circuit LAT may latch the phase difference code Dbbpd and a phase difference inversion code Dbbpdb, which are results of the phase difference, respectively, to the fourth node n4 and the third node n3.

The differential transistor pair MP may include a first transistor MN1 and a second transistor MN2. The control terminal of the first transistor MN1 is connected to the first node n1, the first terminal of the first transistor MN1 is connected to the third node n3, and the second terminal of the first transistor MN1 may be grounded. The control terminal of the second transistor MN2 is connected to the second node n2, the first terminal of the second transistor MN2 is connected to the fourth node n4, and the second terminal of the second transistor MN2 may be grounded. According to some embodiments, the first terminal may be a drain terminal and the second terminal may be a source terminal.

The latch circuit LAT may include a pair of inverters that are feedback-connected to each other between the third node n3 and the fourth node n4.

When the phase of the buffering reference signal Srb leads the phase of the buffering divided signal Sdb, the transition point of the buffering reference signal Srb arrives first and the first transistor MN1 is turned on to allow current to flow. Through the turn-on operation of the first transistor MN1, the phase difference inversion code Dbbpdb may be latched at a logic ‘low’ level at the fourth node n4, and the phase difference code Dbbpd may be latched at a logic ‘high’ level at the third node n3. When the phase of the buffering divided signal Sdb leads the phase of the buffering reference signal Srb, the transition point of the buffering divided signal Sdb arrives first and the second transistor MN2 is turned on to allow current to flow. Through the turn-on operation of the second transistor MN2, the phase difference code Dbbpd may be latched at a logic ‘low’ level at the fourth node n4 and the phase difference inversion code Dbbpdb may be latched at a logic ‘high’ level at the third node n3. In some embodiments, the phase difference code Dbbpd may be latched with the period of the reference signal Sref.

The precharge circuit PRE may provide a precharge voltage Vpre to the third node n3 and the fourth node n4 before the amplification operation of the differential transistor pair MP and the latch circuit LAT. According to some embodiments, the precharge voltage Vpre may be a high voltage of a logic high level, and the precharge circuit PRE may provide the precharge voltage Vpre to the third node n3 and the fourth node n4 with a period of the reference signal Sref.

As shown in FIG. 1, the digital loop filter 13 may receive the phase difference code Dbbpd from the phase detector 11. The digital loop filter 13 may filter the phase difference code Dbbpd. According to some embodiments, the digital loop filter 13 may include a first path and a second path for the phase difference code Dbbpd. The first path may filter phase noise for the phase difference code Dbbpd. The second path may filter the frequency domain offset for the phase difference code Dbbpd that flows from the phase detector 11 to the digital loop filter 13, and then, to the oscillator 15. The digital loop filter 13 may provide a filtering signal Df in which the offset and phase noise are filtered in the frequency domain with respect to the phase difference code Dbbpd to the oscillator 15.

The oscillator 15 may output an output signal Sout based on a filtering signal Df. For example, the frequency of the output signal Sout may be adjusted by the filtering signal Df. According to some embodiments, the oscillator 15 may be an LC oscillator or a ring oscillator, but is not limited to the above examples.

According to some embodiments, the low-noise characteristic of the output signal Sout of the oscillator 15 may be satisfied as the phase noise is filtered by the first path of the digital loop filter 13 described above. As the frequency offset is filtered by the second path of the digital loop filter 13, the frequency of the output signal Sout of the oscillator 15 may be adjusted to the target frequency.

As shown in FIG. 1, the divider 16 may receive the output signal Sout from the oscillator 15. The divider 16 may receive a division control signal Ddc and a phase selection signal Dps based on a fractional signal Dfrac and an integer signal Dint. The divider 16 may divide the frequency of the output signal Sout based on a division control signal Ddc and a phase selection signal Dps. The divider 16 may divide the output signal Sout by a fractional division ratio based on a division control signal Ddc.

The divider 16 may sample the output signal Sout into one phase section (ex. rising edges, falling edges, etc.) to perform a division operation. The divider 16 may perform a high-speed division operation and a low-power division operation through the sampling operation.

The divider 16 may output a divided signal Sdiv to the phase detector 11. As a result, the output signal Sout, generated through the phase detector 11, digital loop filter 13, and oscillator 15 based on the reference signal Sref, may be divided and fed back (based on the fractional signal Dfrac and the integer signal Dint) to the phase detector 11. By repeatedly feeding back, the frequency of the output signal Sout may be adjusted to a target frequency corresponding to the fractional signal Dfrac and the integer signal Dint. Hereinafter, the phase detector 11, digital loop filter 13, oscillator 15, and divider 16 may be referred to as a ‘feedback loop’.

According to some embodiments, the divider 16 may include, but is not limited to, a multi-modulus divider MMD and a phase selector.

The delta-sigma modulator 17 may receive the fractional signal Dfrac from an external device of the digital phase lock loop circuit 10. The fractional signal Dfrac may be frequency division ratio data related to the frequency to be obtained through the divider 16. For example, the fractional signal Dfrac may be a signal corresponding to the fractional part of the division ratio of the divider 16. The delta-sigma modulator 17 may generate a quantization noise signal Ddsm based on a fractional signal Dfrac. The quantization noise signal Ddsm may be output to the accumulation circuit 18.

According to some embodiments, the delta-sigma modulator 17 may perform an addition operation on the quantization noise signal Ddsm and the integer signal Dint. The integer signal Dint may be frequency division ratio data related to the frequency to be obtained through the divider 16. For example, the integer signal Dint may correspond to the integer part of the division ratio of the divider 16. According to some embodiments, the delta-sigma modulator 17 may output a frequency division control signal Ddc to the divider 16 as a result of the addition operation.

The delta-sigma modulator 17 may control the sampling operation of the divider 16 by providing a phase selection signal Dps to the divider 16 and may provide the phase selection signal Dps to the correction circuit 19.

The delta-sigma modulator 17 may be implemented as any one of modulators having various orders, such as MASH (Multi-stAge noise SHaping)-1, MASH1-1, MASH1-1-1, etc., but is not limited to the above examples.

The accumulation circuit 18 may generate a quantization noise code Dqe by accumulating the quantization noise signal Ddsm. For example, the accumulation circuit 18 may perform an accumulation operation on the difference between the fractional signal Dfrac and the quantization noise signal Ddsm, and generate the quantization noise code Dqe based on the result of the accumulation operation.

According to some embodiments, the quantization noise code Dqe may have both of a negative value and a positive value. For example, if the phase of the reference signal Sref leads the phase of the divided signal Sdiv, the quantization noise code Dqe may have the negative value. If the phase of the divided signal Sdiv leads the phase of the reference signal Sref, the quantization noise code Dqe may have the positive value. In some embodiments, the expected value for the quantization noise code Dqe may be zero (0). Unlike as illustrated in FIG. 1, according to some embodiments, the accumulation circuit 18 may be implemented together with the delta-sigma modulator 17.

The correction circuit 19 may receive the quantization noise code Dqe, the phase selection signal Dps, and the phase difference code Dbbpd, and perform a correction operation on the quantization noise code Dqe based on the phase selection signal Dps and the phase difference code Dbbpd to generate the first quantization noise correction code Dqen and the second quantization noise correction code Dqep.

Based on various algorithms such as a “least mean square” (LMS) algorithm, the correction circuit 19 may correct the nonlinearity between the quantization noise code Dqe and the delay operation of the switch capacitor array CSA and may correct the phase error due to the sampling operation of the divider 16. The correction circuit 19 may generate a first quantization noise correction code Dqen and a second quantization noise correction code Dqep that control the delay operation of the switch capacitor array CSA through the correction operation.

In FIG. 3, the correction circuit 19 may include a phase LMS algorithm unit LAp, an absolute value operator ABS, a comparator COM, first to third polynomial operators PO1 to PO3, first to third LMS algorithm units LA1 to LA3, first and second adders ADD1, ADD2, an inverter INV, and first and second multipliers MUL1, MUL2.

The phase LMS algorithm unit LAp may receive the phase selection signal Dps and the phase difference code Dbbpd, and calculate a phase correction coefficient hp for the phase selection signal Dps based on the LMS algorithm. The phase LMS algorithm unit Lap may receive the phase difference code Dbbpd as error information and perform an LMS algorithm to remove correlation between the phase selection signal Dps and the phase difference code Dbbpd, and gradually update the phase correction coefficient hp for the phase selection signal Dps during the execution of the LMS algorithm. According to some embodiments, the phase LMS algorithm unit LAp may update the phase correction coefficient hp at a periodic interval of the reference signal Sref.

The phase LMS algorithm unit LAp may multiply the phase selection signal Dps and the phase correction coefficient hp and provide the result to the first adder ADD1.

The first adder ADD1 may generate a quantization noise correction value DqM by adding the result value of the quantization noise code Dqe and the phase LMS algorithm unit LAp. The quantization noise correction value DqM may be data that corrects the phase error due to the sampling operation of the divider 16 with respect to the quantization noise code Dqe.

The absolute value operator ABS may calculate the quantization noise correction magnitude value D, which is the absolute value of the quantization noise correction value DqM, based on the quantization noise correction value DqM.

The comparator COM may compare the quantization noise correction value DqM with a reference value and output a bit value in response to or based on the comparison result. The comparator COM may output a logic high ‘1’ in response to or based on the quantization noise correction value DqM being greater than a reference value, and may output a logic low ‘0’ in response to or based on the quantization noise correction value DqM being less than or equal to ‘0’. According to some embodiments, the comparator COM may compare the quantization noise correction value DqM with a reference value of ‘0’, and output a logic high ‘1’ in response to or based on the quantization noise correction value DqM being greater than ‘0’, and output a logic low ‘0’ in response to or based on the quantization noise correction value DqM being less than or equal to ‘0’.

The comparator COM may provide a bit value corresponding to the comparison result to the inverter INV and the second multiplier MUL2. The inverter INV may invert the bit value of the comparator and provide it to the first multiplier MUL1.

Each of the first polynomial operator PO1, the second polynomial operator PO2, and the third polynomial operator PO3 may perform a polynomial operation on a quantization noise correction magnitude value D and may generate a first functional value f1(D), a second functional value f2(D), a third function value f3(D), respectively. According to some embodiments, each of the first to third polynomial operators PO1 to PO3 may perform a different x-th order polynomial operation on a quantization noise correction magnitude value D, where x is a natural number.

For example, the first polynomial operator PO1 may perform a first-order polynomial operation, which is a linear operation, on the quantization noise correction magnitude value D to generate the first function value f1(D). The second polynomial operator PO2 may perform a second-order polynomial operation, which is a nonlinear operation, on the quantization noise correction magnitude value D to generate a second function value f2(D). The third polynomial operator PO3 may perform a third-order polynomial operation, which is a nonlinear operation, on the quantization noise correction magnitude value D to generate a third function value f3(D).

The polynomial operation results of each of the first polynomial operator PO1, the second polynomial operator PO2, and the third polynomial operator PO3 may be uncorrelated with respect to the quantization noise correction magnitude value D, may not interfere with each other, and may be orthogonal to each other. For example, the first function value f1(D) and the second function value f2(D) may have a covariance of zero (0) with respect to the probability density function for the quantization noise correction magnitude value D. For example, when the delta-sigma modulator 17 is MASH1-1, each of the first functional value f1(D), the second functional value f2(D), the third function value f3(D) for the quantization noise correction magnitude value D may be as shown in the following equation 1, but is not limited to this equation. In some other embodiments, each function value may vary depending on the embodiment of the delta-sigma modulator 17.

$${f}_{1} ( D ) = D , \qquad EQUATION 1$$

$${f}_{2} ( D ) = {D}^{2} - \frac{3}{5} D ,$$

$${f}_{3} ( D ) = {D}^{3} - \frac{7}{8} {D}^{2} + \frac{2}{7} D$$

The above D is the quantization noise correction magnitude value D, the above f₁(D) is the first function value f₁(D) for the quantization noise correction magnitude value, the above f₂(D) is the second function value f2(D) for the quantization noise correction magnitude value, and the above f₃(D) is the third function value f₃(D) for the quantization noise correction magnitude value.

The first LMS algorithm unit LA1 may receive the first function value f1(D) and the phase difference code Dbbpd, and calculate a first correction coefficient h1 for the first function value f1(D) based on the LMS algorithm. The first LMS algorithm unit LA1 may receive the phase difference code Dbbpd as error information and perform the LMS algorithm to remove the correlation between the first function value f1(D) and the phase difference code Dbbpd. The first LMS algorithm unit LA1 may gradually update the first correction coefficient h1 for the first function value f1(D) during execution of the LMS algorithm. According to some embodiments, the first LMS algorithm unit LA1 may update the first correction coefficient h1 at a periodic interval of the reference signal Sref.

The first LMS algorithm unit LA1 may multiply the first function value f1(D) and the first correction coefficient h1 and provide the result to the second adder ADD2.

The second LMS algorithm unit LA2 may receive the second function value f2(D) and the phase difference code Dbbpd, and calculate a second correction coefficient h2 for the second function value f2(D) based on the LMS algorithm. The second LMS algorithm unit LA2 may receive the phase difference code Dbbpd as error information and perform the LMS algorithm in a direction of removing the correlation between the second function value f2(D) and the phase difference code Dbbpd. The second LMS algorithm unit LA2 may gradually update the second correction coefficient h2 for the second function value f2(D) during execution of the LMS algorithm. According to some embodiments, the second LMS algorithm unit LA2 may update the second correction coefficient h2 at a periodic interval of the reference signal Sref.

The second LMS algorithm unit LA2 may multiply the second function value f2(D) and the second correction coefficient h2 and provide the result to the second adder ADD2.

The third LMS algorithm unit LA3 may receive a third function value f3(D) and the phase difference code Dbbpd, and calculate a third correction coefficient h3 for the third function value f3(D) based on the LMS algorithm. The third LMS algorithm unit LA3 may receive the phase difference code Dbbpd as error information and perform the LMS algorithm in the direction of removing the correlation between the third function value f3(D) and the phase difference code Dbbpd. The third LMS algorithm unit LA3 may gradually update the third correction coefficient h3 for the third function value f3(D) during execution of the LMS algorithm. According to some embodiments, the third LMS algorithm unit LA3 may update the third correction coefficient h3 at a periodic interval of the reference signal Sref.

The third LMS algorithm unit LA3 may multiply the third function value f3(D) and the third correction coefficient h3 and provide the result to the second adder ADD2.

The second adder ADD2 may add the results of the first to third LMS algorithm units LA1 to LA3 to generate a pre-quantization noise correction code Dpre. The generated pre-quantization noise correction code Dpre may be provided to the first and second multipliers MUL1, MUL2.

The correction circuit 19 may generate a pre-quantization noise correction code Dpre by correcting the nonlinearity between the quantization noise code Dqe and a delay operation of a switch capacitor array CSA through the first to third polynomial operators PO1 to PO3, the first to third LMS algorithm units LA1 to LA3, and the second adder ADD2. According to some embodiments, the correction circuit 19 may reduce the time required for the pre-quantization noise correction code Dpre to converge by removing the correlation between the result values of the first to third polynomial operators PO1 to PO3 through the non-correlation between the first to third polynomial operators PO1 to PO3.

The first multiplier MUL1 may generate the first quantization noise correction code Dqen by multiplying the pre-quantization noise correction code Dpre and a bit value received from an inverter INV. The second multiplier MUL2 may generate the second quantization noise correction code Dqep by multiplying the pre-quantization noise correction code Dpre and the bit value received from the comparator COM. Each of the first and second multipliers MUL1, MUL2 may receive mutually exclusive bit values from the inverter INV and the comparator COM. For example, in response to or based on the first multiplier MUL1 receiving a ‘1’ from the inverter INV, the second multiplier MUL2 may receive a ‘0’ from the comparator COM. Each of the first and second multipliers MUL1, MUL2 may receive mutually exclusive bit values from the inverter INV or the comparator COM, such that, if one of the first quantization noise correction code Dqen and the second quantization noise correction code Dqep is a valid code, the other may be a null code.

In response to or based on the quantization noise correction value DqM being greater than ‘0’, the first multiplier MUL1 may generate the first quantization noise correction code Dqen which is ‘0’, and the second multiplier MUL2 may generate the second quantization noise correction code Dqep which is identical to the pre-quantization noise correction code Dpre.

In response to or based on the quantization noise correction value DqM being less than or equal to ‘0’, the first multiplier MUL1 may generate the first quantization noise correction code Dqen that is identical to the pre-quantization noise correction code Dpre, and the second multiplier MUL2 may generate a second quantization noise correction code Dqep that is ‘0’.

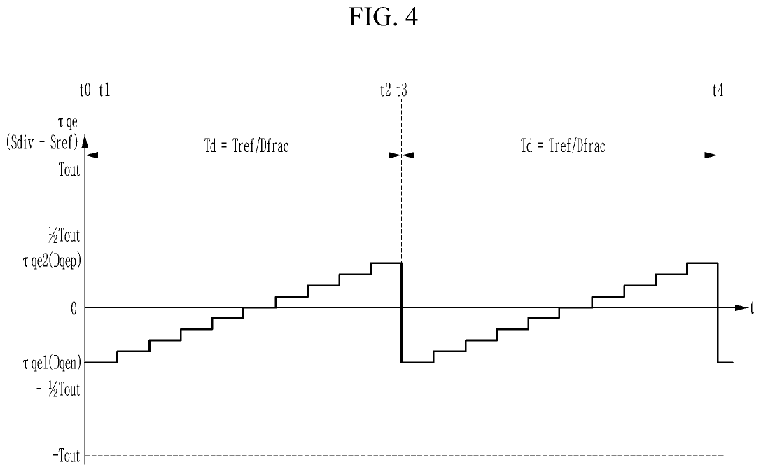

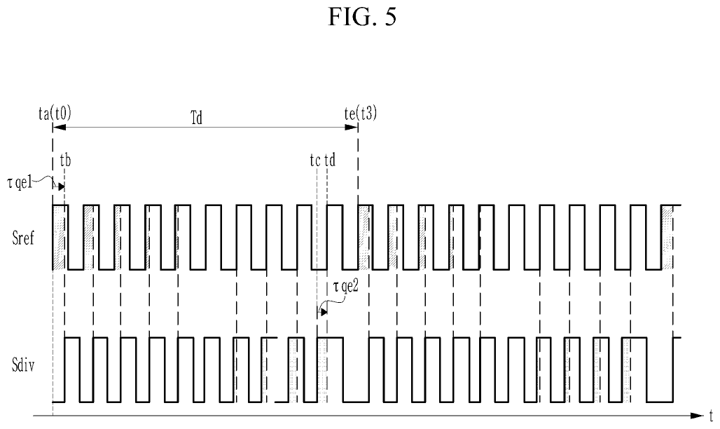

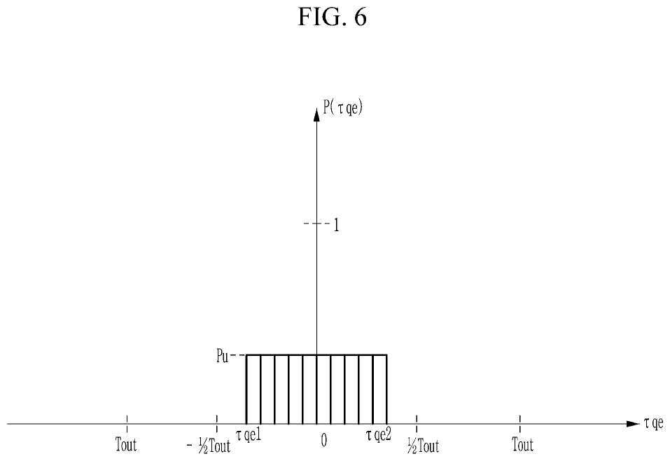

FIGS. 4 to 6 are diagrams illustrating quantization noise between a divided signal and a reference signal input to a phase detector according to some embodiments. Specifically, FIG. 4 illustrates an example of quantization noise τqe between the divided signal Sdiv and the reference signal Sref when the delta-sigma modulator 17 of FIG. 1 is implemented with MASH-1. FIG. 5 illustrates time-series waveforms of the reference signal Sref and the divided signal Sdiv according to the quantization noise τqe in FIG. 4. FIG. 6 illustrates a probability density function according to the quantization noise τqe in FIG. 4.

Referring to FIGS. 1, 4, 5, and 6, at time t1, the phase of the reference signal Sref may lead the phase of the divided signal Sdiv by the first quantization noise τqe1. At a time near time t1, the rising edge of the reference signal Sref may arrive before the rising edge of the divided signal Sdiv. Referring to FIG. 5 as an example, at time ta, the reference signal Sref may transition from a logic low level to a logic high level. At tb time, the divided signal Sdiv may transition from logic low level to logic high level.

The quantization noise τqe corresponds to the quantization noise code Dqe of FIG. 1 and represents the phase of the divided signal Sdiv based on the phase of the reference signal Sref, so the first quantization noise τqe1 is a negative value and may correspond to the first quantization noise correction code Dqen. The phase detector 11 may compensate for the first quantization noise τqe1 by performing a delay operation on the reference signal Sref based on the first quantization noise correction code Dqen.

The amplitude of the first quantization noise τqe1 corresponds to the temporal interval between time points ta and tb, and may be less than half the length of the output period Tout. The output period Tout may be the period of the output signal Sout.

From time t1 to time t3, the quantization noise τqe between the divided signal Sdiv and the reference signal Sref gradually increases and may change from a negative value to a positive value. Referring to FIG. 5 as an example, the rising edge of the divided signal Sdiv may be gradually brought forward and arrive earlier than the rising edge of the reference signal Sref depending on the variation of the quantization noise τqe from the time point tb to the time point the.

At time t2, the phase of the divided signal Sdiv may lead the phase of the reference signal Sref by the second quantization noise τqe2. At a time near time t2, the rising edge of the divided signal Sdiv may arrive before the rising edge of the reference signal Sref. Referring to FIG. 5 as an example, at time tc, the divided signal Sdiv may transition from a logic low level to a logic high level. At time td, the reference signal Sref may transition from a logic low level to a logic high level.

Since the quantization noise τqe represents the phase of the divided signal Sdiv with respect to the phase of the reference signal Sref, the second quantization noise τqe2 is a positive value and may correspond to the second quantization noise correction code Dqep. The phase detector 11 may compensate for the second quantization noise τqe2 by performing a delay operation on the divided signal Sdiv based on the second quantization noise correction code Dqep. The amplitude of the second quantization noise τqe2 corresponds to the time interval between time points tc and td, and may be less than half the length of the output period Tout.

The quantization noise τqe may vary repeatedly with the quantization noise period Td. The variation pattern of quantization noise τqe between time points t0 and t3 is repeated between time points t3 and t4, and may also vary repeatedly with the quantization noise period Td after time points t4. The quantization noise period Td may be calculated by dividing the fractional signal Dfrac by the reference period Tref. The reference period Tref may be the period of the reference signal Sref.

Referring to FIG. 6 as an example, the probability density function P(τqe) for quantization noise qe may have a constant value, ‘Pu’. The phase detector 11 narrows the amplitude range of quantization noise τqe that occurs with a certain probability to half of the output period Tout, thereby reducing thermal noise due to the compensation operation in general and improving the power efficiency of the compensation operation. In addition, through the improvement of the above thermal noise, the digital phase lock loop circuit 10 may have a wide bandwidth and improved jitter performance.

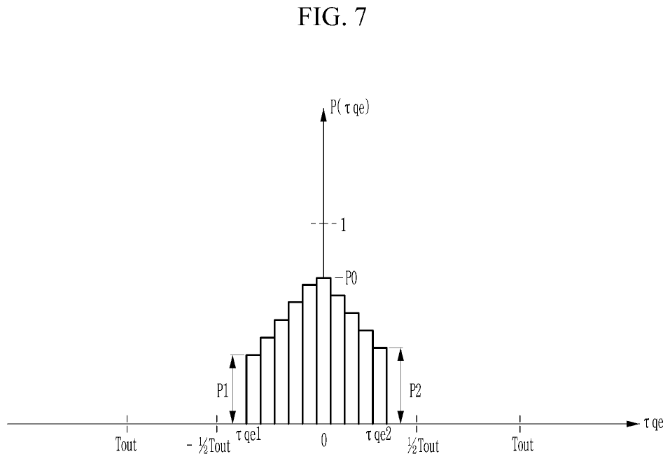

FIG. 7 illustrates an example of a probability density function due to quantization noise occurring in a digital phase lock loop circuit according to some embodiments. Specifically, FIG. 7 shows a probability density function according to quantization noise τqe between a divided signal Sdiv and a reference signal Sref when the delta-sigma modulator 17 of FIG. 1 is implemented as, for example, MASH1-1.

Referring to FIG. 7, the probability density function P(τqe) for quantization noise τqe may be concentrated around ‘0’. When the phase between the divided signal Sdiv and the reference signal Sref is the same, i.e., when the quantization noise τqe is ‘0’, the probability density function P(τqe) may have a maximum value of ‘P0’. Additionally, the probability density function P (qe) may have ‘P1’ smaller than ‘P0’ in response to the first quantization noise τqe1, and ‘P2’ smaller than ‘P0’ in response to the second quantization noise τqe2.

The phase detector 11 may perform a compensation operation for quantization noise τqe by reflecting the amplitude of the probability density function P(τqe), thereby minimizing thermal noise and improving power efficiency. The phase detector 11 may perform compensation operations more frequently for compensation operations that generate relatively less thermal noise. For example, in response to a case where the probability density function P(τqe) for the quantization noise τqe is at its maximum value, the phase detector 11 may not perform a delay operation, thereby reducing thermal noise due to the compensation operation and improving power efficiency of the compensation operation.

In some embodiments, the amplitude of the quantization noise τqe may be less than half the length of the output period Tout. Since the quantization noise τqe has a narrow range of magnitudes instead of having both negative and positive values, the phase detector 11 may reduce thermal noise due to the compensation operation in general and improve the power efficiency of the compensation operation. In addition, through the improvement of the above thermal noise, the digital phase lock loop circuit 10 may have a wide bandwidth and improved jitter performance.

Although FIG. 7 illustrates the probability density function P(τqe) for quantization noise τqe when the delta-sigma modulator is implemented with MASH1-1, it is not limited to the above example, and the characteristics of the probability density function P(τqe) of FIG. 7 may also be applied to the digital phase lock loop circuit 10 that adopts various orders such as MASH1-1-1.

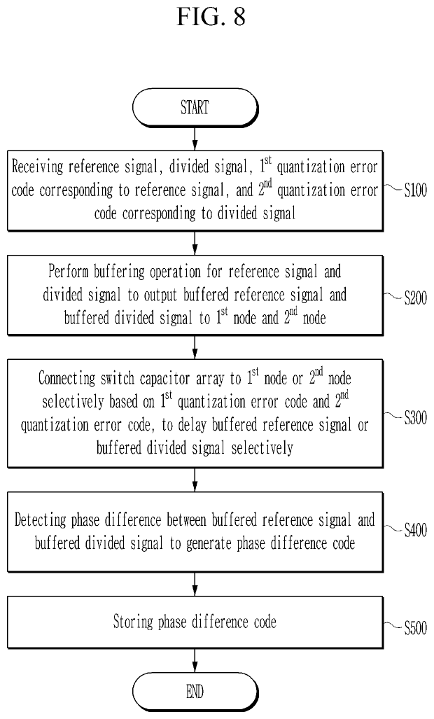

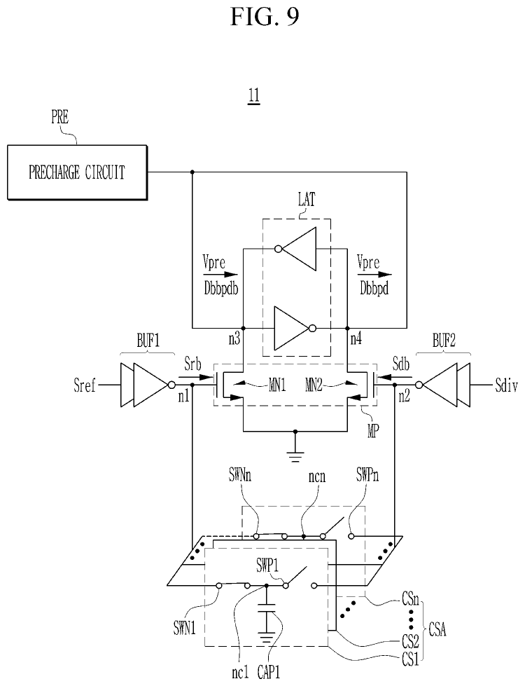

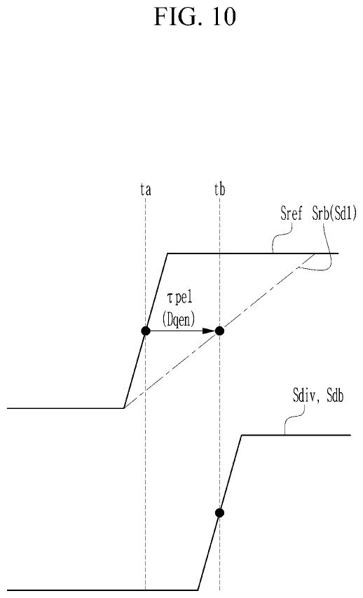

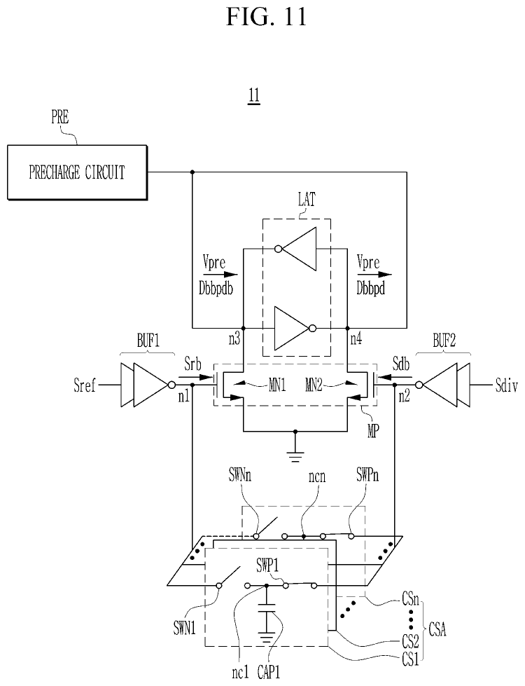

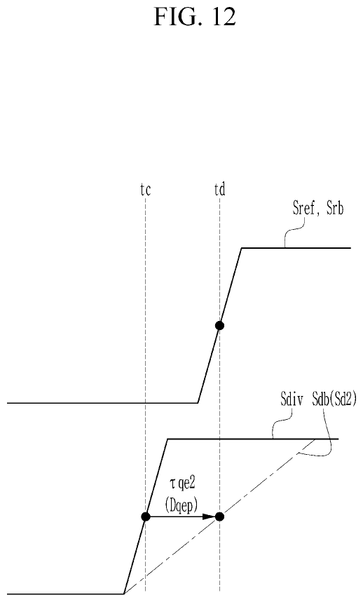

FIG. 8 is a flowchart illustrating a method of operation of a digital phase lock loop circuit according to some embodiments. FIGS. 9 to 12 are drawings for explaining an operation method of a digital phase lock loop circuit according to some embodiments. Specifically, FIGS. 9 and 10 are drawings for explaining the delay operation for the reference signal Sref. FIGS. 11 and 12 are drawings for explaining the delay operation for the divided signal Sdiv.

Referring to FIGS. 1, 2, 3, and 8, the phase detector 11 receives the reference signal Sref, the divided signal Sdiv, the first quantization noise correction code Dqen, and the second quantization noise correction code Dqep (S100).

The first quantization noise correction code Dqen corresponds to a reference signal Sref and may include delay information for the reference signal Sref. The second quantization noise correction code Dqep corresponds to the divided signal Sdiv and may include delay information for the divided signal Sdiv. The phase detector 11 may perform a compensation operation for quantization noise between the reference signal Sref and the divided signal Sdiv based on the first quantization noise correction code Dqen and the second quantization noise correction code Dqep.

In S200, the phase detector 11 performs a buffering operation on the reference signal Sref and the divided signal Sdiv, outputting a buffering reference signal Srb to the first node n1 and a buffering divided signal Sdb to the second node n2.

The first buffer circuit BUF1 may receive the reference signal Sref, perform a buffering operation on the reference signal Sref, and output the buffering reference signal Srb to the first node n1. The second buffer circuit BUF2 may receive the divided signal Sdiv, perform a buffering operation on the divided signal Sdiv, and output a buffering divided signal Sdb to the second node n2.

In S300, the phase detector 11 selectively connects the switch capacitor array CSA to the first node n1 or the second node n2 based on the first quantization noise correction code Dqen and the second quantization noise correction code Dqep to selectively delay one signal between the buffering reference signal Srb or the buffering divided signal Sdb.

In FIGS. 9 and 10, when the phase of the reference signal Sref leads the phase of the divided signal Sdiv, the first quantization noise correction code Dqen may be a valid code and the second quantization noise correction code Dqep may be a null code. As an example, referring to FIG. 10, in response to or based on the reference signal Sref transitioning from a logic low level to a logic high level at a time point ta and the divided signal Sdiv transitioning from a logic low level to a logic high level at a time point tb that lags behind the time point ta, the first quantization noise correction code Dqen may be a valid code and the second quantization noise correction code Dqep may be a null code.

Due to the mutually exclusive characteristics of the first quantization noise correction code Dqen and the second quantization noise correction code Dqep, at least a portion of the first switches SWN1 to SWNn may be shorted and the second switches SWP1 to SWPn may be opened. According to the short-circuit operation for at least a portion of the first switches SWN1 to SWNn and the open-circuit operation for the second switches SWP1 to SWPn, the first node n1 may be electrically connected to at least a portion of the switch capacitor array CSA and the second node n2 may be electrically isolated from the switch capacitor array CSA.

In response to or based on at least a portion of the switch capacitor array CSA being electrically connected to the first node n1, a voltage slope at an edge of the buffering reference signal Srb may be less steep and a transition point centered around the edge of the buffering reference signal Srb may be delayed. By performing a delay operation for the buffering reference signal Srb, the buffering reference signal Srb may act as a first delay signal Sd1 for the reference signal Sref, and quantization noise between the reference signal Sref and the divided signal Sdiv may be compensated. As an example, referring to FIG. 10, in response to at least a portion of the switch capacitor array CSA being electrically connected to the first node n1, the voltage slope at the rising edge of the buffering reference signal Srb may become less steep and the transition point of the buffering reference signal Srb is delayed from the time point ta to the time point tb so that the first quantization noise t qe1 may be compensated.

In FIGS. 11 and 12, when the phase of the divided signal Sdiv leads the phase of the reference signal Sref, the second quantization noise correction code Dqep may be a valid code and the first quantization noise correction code Dqen may be a null code. Referring to FIG. 12, as an example, in response to or based on the divided signal Sdiv transitioning from a logic low level to a logic high level at a time point tc and the reference signal Sref transitioning from a logic low level to a logic high level at a time point td which lags behind the time point tc, the second quantization noise correction code Dqep may be a valid code and the first quantization noise correction code Dqen may be a null code.

Due to the mutually exclusive properties of the first quantization noise correction code Dqen and the second quantization noise correction code Dqep, the first switches SWN1 to SWNn may be opened and at least a portion of the second switches SWP1 to SWPn may be opened. According to the short-circuit operation of the first switch SWN1 to SWNn and the open-circuit operation of at least a portion of the second switch SWP1 to SWPn, the first node n1 may be electrically isolated from the switch capacitor array CSA and the second node n2 may be electrically connected to at least a portion of the switch capacitor array CSA.

In response to or based on at least a portion of the switch capacitor array CSA being electrically connected to the second node n2, the voltage slope at the edge of the buffering divided signal Sdb may be less steep and the transition point, which is the center of the edge of the buffering divided signal Sdb, may be delayed. By performing a delay operation on the buffering divided signal Sdb, the buffering divided signal Sdb may act as a second delay signal Sd2 for the divided signal Sdiv, and the quantization noise between the reference signal Sref and the divided signal Sdiv may be compensated. As an example, referring to FIG. 12, in response to or based on at least a portion of the switch capacitor array CSA being electrically connected to the second node n2, the voltage slope at the rising edge of the buffering divided signal Sdb may be less steep and the transition point of the buffering divided signal Sdb is delayed from the time point tc to the time point td so that the second quantization noise τqe2 may be compensated.

Although operation S200 is illustrated as preceding operation S300 in FIG. 8, the present disclosure is not limited to the above example embodiment. In an embodiment, operations S200 and S300 may be performed together.

In S400, the phase detector 11 detects the phase difference between the buffering reference signal Srb and the buffering divided signal Sdb and generates a phase difference code Dbbpd.

The differential transistor pair MP and the latch circuit LAT may detect the phase difference between the compensated buffering reference signal Srb and the buffering divided signal Sdb, and generate the phase difference code Dbbpd and a phase difference inversion code Dbbpdb at the fourth node n4 and the third node n3.

Before the detection operation of the differential transistor pair MP and the latch circuit LAT, the third node n3 and the fourth node n4 may be precharged with a precharge voltage Vpre, and a voltage corresponding to the phase difference code Dbbpd may be formed at the fourth node n4 through the phase difference detection operation of the differential transistor pair MP and the latch circuit LAT.

In S500, The phase detector 11 stores the phase difference code Dbbpd.

The latch circuit LAT may latch and store the phase difference code Dbbpd and the phase difference inversion code Dbbpdb in the fourth node n4 and the third node n3, respectively.

Although step S400 is illustrated as preceding operation S500 in FIG. 8, the present disclosure is not limited to the example embodiment. In an embodiment, steps S400 and S500 may be performed together.

Thereafter, the phase difference code Dbbpd generated from the phase detector 11 based on the reference signal Sref may be provided to the digital loop filter 13. The output signal Sout generated through the phase detector 11, digital loop filter 13 and oscillator 15 may be fed back based on the fractional signal Dfrac and the integer signal Dint and provided to the phase detector 11. By repeatedly feeding back, the frequency of the output signal Sout may be adjusted to a target frequency corresponding to the fractional signal Dfrac and the integer signal Dint, and the quantization noise between the reference signal Sref and the divided signal Sdiv in the feedback process may be repeatedly compensated through steps S100 to S500.

The digital phase lock loop circuit 10 may improve noise and power degradation caused by thermal noise generated in the compensation operation through the quantization noise compensation operation of steps S100 to S500. Additionally, the digital phase lock loop circuit 10 may improve area efficiency through the arrangement and operation of a switch capacitor array CSA.

The digital phase lock loop circuit 10 may improve the convergence time required to correct nonlinearity and phase error for quantization noise through the first to third polynomial operators PO1 to PO3 and the first to third LMS algorithm units LA1 to LA3 of FIG. 3.

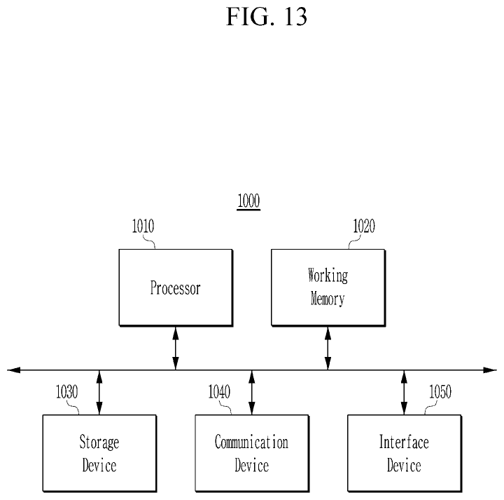

FIG. 13 is a block diagram illustrating an electronic device according to some embodiments.

Referring to FIG. 13, the electronic device 1000 may include a processor 1010, a working memory 1020, a storage device 1030, a communication device 1040, and an interface circuit 1050.

The processor 1010 may operate as a central processing unit of the electronic device 1000. The processor 1010 may include one or more core(s) capable of performing various operations. The core(s) may be implemented as a central processing unit (CPU), a digital signal processing unit (DSP), or a graphics processing unit (GPU).

The working memory 1020 may store data and program codes that are processed or are to be processed by the processor 1010. The working memory 1020 may operate as a main memory device of the electronic device 1000. Working memory 1020 may be implemented as DRAM (Dynamic Random Access Memory) or SRAM (Static Random Access Memory). Working memory 1020 may also be buffer memory or cache memory.

The storage device 1030 may function as an auxiliary memory device of the electronic device 1000. The storage device 1030 may include a non-volatile memory device such as a ROM (Read-Only Memory), an SSD (Solid State Drive), etc. Data stored in the storage device 1030 may be transmitted to the processor 1010 via the bus.

The communication device 1040 may communicate wirelessly or in a wired manner with an external device of the electronic device 1000. The communication device 1040 may receive data for the operation of the electronic device 1000 from an external device. The communication device 1040 may transmit data generated by the processor 1010 to an external device.

The communication device 1040 may include the digital phase lock loop circuit 10 of FIG. 1. Based on the output signal Sout output from the digital phase lock loop circuit 10, the communication device 1040 may generate signals having various frequencies and modulate or demodulate the generated signals. The communication device 1040 may improve noise and power degradation caused by thermal noise generated in compensation operation and improve area efficiency through the configuration and operation of the digital phase lock loop circuit 10 in FIGS. 1 to 12 described above. Additionally, the communication device 1040 may improve the convergence time required to correct nonlinearity and phase error for quantization noise.

The interface circuit 1050 may include various input/output devices for communicating with external devices. For example, the interface circuit 1050 may include at least one of various output devices, such as a monitor, a printer, or a lamp. The interface circuit 1050 may include at least one of various input devices such as a keyboard, a touchpad, a mouse, a microphone, etc.

Although the embodiments of the present disclosure have been described in detail above, the scope of the present disclosure is not limited thereto, and various modifications and improvements made by those skilled in the art using the basic concept of the present disclosure defined in the following claims also fall within the scope of the present disclosure.

1. A digital phase lock loop circuit comprising:
a phase detector configured to:
receive a first reference signal and a first divided signal,
selectively perform a delay operation on one of a second reference signal corresponding to the first reference signal and a second divided signal corresponding to the first divided signal, based on a first quantization noise correction code and a second quantization noise correction code, and
output a phase difference code based on a phase difference between the second reference signal and the second divided signal on either of which the delay operation is performed;
a digital loop filter configured to filter the phase difference code;
an oscillator configured to generate an output signal based on the filtered phase difference code;
a delta-sigma modulator configured to output a quantization noise signal and a division control signal based on first division ratio data and second division ratio data for the output signal;
an accumulation circuit configured to output a quantization noise code by performing an accumulation operation on the quantization noise signal;
a divider configured to output the first divided signal by dividing a frequency of the output signal based on the division control signal; and
a correction circuit configured to:
generate the first quantization noise correction code and the second quantization noise correction code by performing a correction operation on the quantization noise code, and
provide the first quantization noise correction code and the second quantization noise correction code to the phase detector.

2. The digital phase lock loop circuit of claim 1, wherein the phase detector includes:
a first buffer circuit configured to output the second reference signal to a first node by performing a buffering operation on the first reference signal,
a second buffer circuit configured to output the second divided signal to a second node by performing a buffering operation on the first divided signal,
a switch capacitor array configured to be electrically connected to the first node based on the first quantization noise correction code and electrically connected to the second node based on the second quantization noise correction code, and
a latch circuit configured to store the phase difference code.

3. The digital phase lock loop circuit of claim 2, wherein, based on at least a portion of the switch capacitor array being electrically connected to the first node, the switch capacitor array is further configured to be disconnected from the second node.

4. The digital phase lock loop circuit of claim 3, wherein, based on at least a portion of the switch capacitor array being electrically connected to the first node, a voltage slope of the second reference signal is changed.

5. The digital phase lock loop circuit of claim 2, wherein:
the switch capacitor array includes a first switch capacitor element and a second switch capacitor element being connected in parallel with the first switch capacitor between the first node and the second node,
the first switch capacitor element includes a first switch, a second switch, and a first capacitor having a first end being grounded and a second end selectively being connected to the first node through the first switch or to the second node through the second switch, and
the second switch capacitor element includes a third switch, a fourth switch, and a second capacitor having a first end being grounded and a second end selectively being connected to the first node through the third switch or to the second node through the fourth switch.

6. The digital phase lock loop circuit of claim 5, wherein, in response to the first switch being shorted, the second switch and the fourth switch are configured to be opened.

7. The digital phase lock loop circuit of claim 1, wherein:
the first quantization noise correction code and the second quantization noise correction code are mutually exclusive, and
the phase detector is further configured to delay the second reference signal based on the first quantization noise correction code, and delay the second divided signal based on the second quantization noise correction code.

8. The digital phase lock loop circuit of claim 7, wherein one of the first quantization noise correction code and the second quantization noise correction code is a null code.

9. The digital phase lock loop circuit of claim 8, wherein, in case that a phase of the first reference signal leads a phase of the first divided signal, the first quantization noise correction code is a valid code and the second quantization noise correction code is the null code.

10. The digital phase lock loop circuit of claim 8, wherein, in case that a phase of the first reference signal is the same as a phase of the first divided signal, a probability density function for the quantization noise code has a maximum value.

11. The digital phase lock loop circuit of claim 1, wherein the correction circuit includes:
a first operator configured to generate a first function value by performing a linear operation on the quantization noise code,
a first Least Mean Square (LMS) algorithm unit configured to generate a first coefficient for the first function value by performing an LMS algorithm based on the first function value and the phase difference code,
a second operator configured to generate a second function value by performing a nonlinear operation on the quantization noise code, and
a second LMS algorithm unit configured to generate a second coefficient for the second function value by performing an LMS algorithm based on the second function value and the phase difference code, and
wherein the linear operation and the nonlinear operation are uncorrelated.

12. A digital phase lock loop circuit comprising:
a phase detector including:
a first buffer circuit configured to output a second reference signal to a first node by performing a buffering operation on a first reference signal,
a second buffer circuit configured to output a second divided signal to a second node by performing a buffering operation on a first divided signal,
a switch capacitor array at least a portion of which is configured to be selectively connected to the first node and the second node, and
a latch circuit configured to store a phase difference code for a phase difference between the second reference signal and the second divided signal;
a digital loop filter configured to filter the phase difference code;
an oscillator configured to generate an output signal based on the filtered phase difference code;
a delta-sigma modulator configured to output a quantization noise signal and a division control signal based on first division ratio data and second division ratio data for the output signal;
an accumulation circuit configured to output a quantization noise code by performing an accumulation operation on the quantization noise signal;
a divider configured to output the first divided signal by dividing a frequency of the output signal based on the division control signal; and
a correction circuit configured to:
generate a first quantization noise correction code and a second quantization noise correction code by performing a correction operation on the quantization noise code, and
provide the first quantization noise correction code and the second quantization noise correction code to the phase detector.

13. The digital phase lock loop circuit of claim 12, wherein at least a portion of the switch capacitor array is configured to be electrically connected to the first node based on the first quantization noise correction code and to be electrically connected to the second node based on the second quantization noise correction code.

14. The digital phase lock loop circuit of claim 13, wherein the first quantization noise correction code and the second quantization noise correction code are mutually exclusive, and
wherein the phase detector is configured to delay the second reference signal based on the first quantization noise correction code, and to delay the second divided signal based on the second quantization noise correction code.

15. The digital phase lock loop circuit of claim 14, wherein one of the first quantization noise correction code and the second quantization noise correction code is a null code.

16. The digital phase lock loop circuit of claim 15, wherein, in case that a phase of the first reference signal leads a phase of the first divided signal, the first quantization noise correction code is a valid code and the second quantization noise correction code is the null code.

17. The digital phase lock loop circuit of claim 12, wherein, based on at least a portion of the switch capacitor array being selectively connected to the first node and the second node, one of the second reference signal and the second divided signal is selectively delayed, and
wherein the latch circuit is configured to store the phase difference code based on the second reference signal and the second divided signal, either one of which being delayed.

18. The digital phase lock loop circuit of claim 12, wherein:
the switch capacitor array includes a first switch capacitor element and a second switch capacitor element being connected in parallel with the first switch capacitor element between the first node and the second node,
the first switch capacitor element includes a first switch, a second switch, and a first capacitor having a first end being grounded and a second end being selectively connected to the first node through the first switch or to the second node through the second switch, and
the second switch capacitor element includes a third switch, a fourth switch, and a second capacitor having a first end being grounded and a second end being selectively connected to the first node through the third switch or to the second node through the fourth switch.

19. A method of operating a digital phase lock loop circuit, the method comprising:
receiving a first reference signal, a first quantization noise correction code corresponding to the first reference signal, a first divided signal, and a second quantization noise correction code corresponding to the first divided signal;
outputting a buffering reference signal to a first node by performing a buffering operation on the first reference signal, and outputting a buffering divided signal to a second node by performing a buffering operation on the first divided signal;
selectively connecting at least a portion of a switch capacitor array to the first node or the second node, based on the first quantization noise correction code and the second quantization noise correction code;
generate a phase difference code by detecting a phase difference between the buffering reference signal and the buffering divided signal; and
storing the phase difference code.

20. The method of operating the digital phase lock loop circuit of claim 19, wherein the selectively connecting at least a portion of the switch capacitor array includes selectively delaying one of the buffering reference signal and the buffering divided signal, based on the first quantization noise correction code and the second quantization noise correction code.

21. (canceled)

22. (canceled)

23. (canceled)
